(19) United States
(12) Patent Application Publication
(10) Pub. No.: US 2023/0197749 A1
(43) Pub. Date: Jun. 22, 2023

(54) LIGHT DIFFUSER, IMAGE SENSOR PACKAGE HAVING THE SAME, AND MANUFACTURING METHOD THEREOF

(71) Applicant: VisEra Technologies Company Ltd., Hsin-Chu City (TW)

(72) Inventors: Chung-Jung HSU, Hsinchu City (TW); Chin-Chuan HSIEH, Hsin-Chu City (TW); Kuo-Feng LIN, Kaohsiung City (TW)

(21) Appl. No.: 17/560,239

(22) Filed: Dec. 22, 2021

(51) Int. Cl. H01L 27/146; G02B 3/00; G02B 1/00

(52) U.S. Cl. CPC H01L 27/14625; H01L 27/14685; G02B 3/0087; G02B 1/002

(57) ABSTRACT

A light diffuser includes a main body and first fillers. The first fillers are dispersed in the main body. The first fillers include at least one of ZrO₂, Nb₂O₅, Ta₂O₅, SiₓN_{y}, Si, Ge GaP, InP, and PbS, and a diameter of each of the first fillers is in a range from 0.1 μm to 1 μm.

### BACKGROUND

### Field of Invention

The present disclosure relates to a light diffuser, an image sensor package having the light diffuser, and a manufacturing method of the image sensor package.

### Description of Related Art

In order to capture a color image of a scene, an image sensor should be sensitive to a broad spectrum of light. The image sensor reacts to light that is reflected from the scene and can convert the strength of that light into electronic signals. An image sensor, such as a charge-coupled device (CCD) image sensor or a complementary metal-oxide semiconductor (CMOS) image sensor, generally has photoelectric conversion regions that convert incident light into electronic signals. In addition, the image sensor has logic circuits for transmitting and processing the electronic signals. Image sensors are widely applied in many fields, as well as in devices such as light sensors, proximity sensors, time-of-flight (TOF) cameras, spectrometers, smart sensors used in the Internet of things (TOT), and sensors for advanced driver assistance systems (ADAS), for example.

Although existing image sensor packages have been adequate for their intended purposes, they have not been entirely satisfactory in all respects. For example, the scattering capability of a light diffuser over a photoelectric conversion region remains to be improved.

### SUMMARY

An aspect of the present disclosure is to provide a light diffuser.

According to an embodiment of the present disclosure, a light diffuser includes a main body and first fillers. The first fillers are dispersed in the main body. The first fillers include at least one of ZrO₂, Nb₂O₅, Ta₂O₅, SiₓN_{y}, Si, Ge GaP, InP, and PbS, and a diameter of each of the first fillers is in a range from 0.1 μm to 1 μm.

In some embodiments of the present disclosure, a refractive index of the first fillers is higher than a refractive index of the main body.

In some embodiments of the present disclosure, a weight ratio of the first fillers to a combination of the main body and the first fillers is in a range from 10% to 30%.

In some embodiments of the present disclosure, the light diffuser further includes second fillers dispersed in the main body. A refractive index of the second fillers is lower than a refractive index of the first fillers.

In some embodiments of the present disclosure, the refractive index of the second fillers is lower than a refractive index of the main body.

In some embodiments of the present disclosure, the second fillers include SiO₂.

In some embodiments of the present disclosure, a diameter of each of the second fillers is in a range from 1 μm to 10 μm.

In some embodiments of the present disclosure, a weight ratio of the second fillers to a combination of the main body, the first fillers, and the second fillers is in a range from 20% to 50%.

In some embodiments of the present disclosure, the main body is a photoresist layer including epoxy or acrylic resin.

In some embodiments of the present disclosure, there is no TiO₂ located in the main body.

An aspect of the present disclosure is to provide an image sensor package.

According to an embodiment of the present disclosure, an image sensor package includes a semiconductor substrate and a light diffuser. The semiconductor substrate includes a photoelectric conversion region. The light diffuser is over the semiconductor substrate, and is configured to scatter incident light to the photoelectric conversion region. The light diffuser includes a main body and first fillers. The first fillers are dispersed in the main body. The first fillers include at least one of ZrO₂, Nb₂O₅, Ta₂O₅, SiₓN_{y}, Si, Ge GaP, InP, and PbS, and a diameter of each of the first fillers is in a range from 0.1 μm to 1 μm.

In some embodiments of the present disclosure, the image sensor package further includes a metal-insulator-metal (MIM) structure between the light diffuser and the semiconductor substrate.

In some embodiments of the present disclosure, the light diffuser is directly on the MIM structure.

In some embodiments of the present disclosure, a refractive index of the first fillers is higher than a refractive index of the main body.

In some embodiments of the present disclosure, the image sensor package further includes second fillers dispersed in the main body. A refractive index of the second fillers is lower than a refractive index of the first fillers and a refractive index of the main body.

In some embodiments of the present disclosure, the second fillers comprise SiO₂.

In some embodiments of the present disclosure, a diameter of each of the second fillers is in a range from 1 μm to 10 μm.

In some embodiments of the present disclosure, a weight ratio of the second fillers to a combination of the main body, the first fillers, and the second fillers is in a range from 20% to 50%.

An aspect of the present disclosure is to provide a manufacturing method of an image sensor package.

According to an embodiment of the present disclosure, a manufacturing method of an image sensor package includes mixing first fillers with a resin to form a solution, wherein the first fillers include at least one of ZrO₂, Nb₂O₅, Ta₂O₅, SiₓN_{y}, Si, Ge GaP, InP, and PbS, and a diameter of each of the first fillers is in a range from 0.1 μm to 1 μm; dispensing the solution to a semiconductor substrate; spreading the solution to cover the semiconductor substrate by spin coating; and curing the solution to form a light diffuser, wherein the resin is cured to be a main body of the light diffuser.

In some embodiments of the present disclosure, the method further includes prior to dispensing the solution to the semiconductor substrate, mixing second fillers with the resin, wherein a refractive index of the second fillers is lower than a refractive index of the first fillers.

In the aforementioned embodiments of the present disclosure, since the first fillers dispersed in the main body of the light diffuser have high refractive index, and the first fillers include at least one of ZrO₂, Nb₂O₅, Ta₂O₅, SiₓN_{y}, Si, Ge GaP, InP, and PbS, the light diffuser can have high scattering capability and prevent photolysis. Moreover, the first fillers have low reactivity with organics, and thus the selection of materials for the main body of the light diffuser is more flexible. As a result, the main body with the first fillers may be formed over the semiconductor substrate by spin coating without a compression molding process.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view of an image sensor package according to one embodiment of the present disclosure.

FIGS. 2 and 3 are schematic views at various stages of a manufacturing method of the image sensor package of FIG. 1.

FIG. 4 is a schematic view of a light diffuser when light passes through according to one embodiment of the present disclosure.

FIG. 5 is a Transmission rate-Wavelength relationship chart with respect to incident light with different incident angles passing through the light diffuser of the image sensor package of FIG. 1.

FIG. 6 is a Luminous intensity-Viewing angle relationship chart with respect to two light diffusers and one dry film, in which the two light diffusers include different proportions of fillers.

FIG. 7 is a distribution diagram of luminous intensity with respect to the light diffuser including a lower proportion of the fillers of FIG. 6 after light passing through the light diffuser.

FIG. 8 is a partial enlarged view of the light diffuser of FIG. 1.

FIG. 9 is a schematic view for a phase contrast which occurs in the light diffuser of FIG. 8.

FIG. 10 is a partial enlarged view of a light diffuser according to one embodiment of the present disclosure.

FIG. 11 is a schematic view for a phase contrast which occurs in the light diffuser of FIG. 10.

FIG. 12 is a partial enlarged view of a light diffuser according to one embodiment of the present disclosure.

FIG. 13 is a schematic view for a phase contrast which occurs in the light diffuser of FIG. 12.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

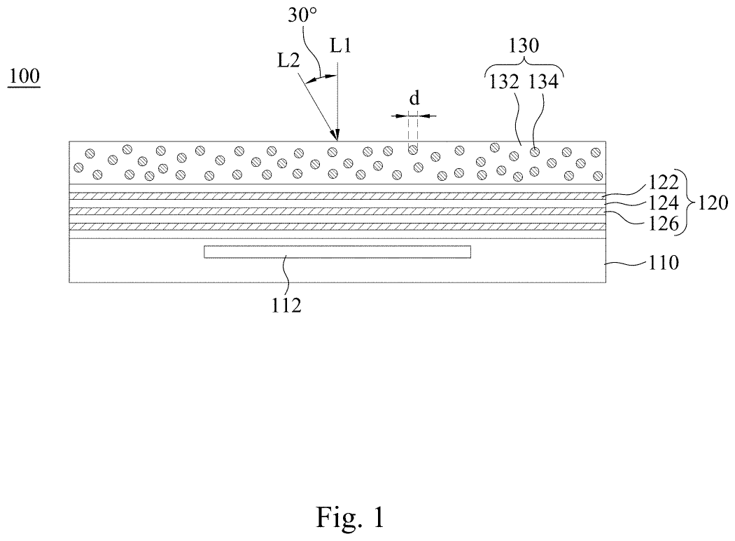

FIG. 1 is a cross-sectional view of an image sensor package 100 according to one embodiment of the present disclosure. The image sensor package 100 includes a semiconductor substrate 110 and a light diffuser 130. The semiconductor substrate 110 includes a photoelectric conversion region 112. The semiconductor substrate 110 may be a silicon wafer or chip, and the photoelectric conversion region 112 may include at least one photodiode. The light diffuser 130 is over the semiconductor substrate 110, and is configured to scatter incident light (e.g., light L1 or L2) to the underlying photoelectric conversion region 112 of the semiconductor substrate 110. The light diffuser 130 includes a main body 132 and a plurality of first fillers 134. In some embodiments, the main body 132 may be a photoresist layer including epoxy or acrylic resin. The first fillers 134 are uniformly dispersed in the main body 132, but not regularly arranged in the main body 132. The first fillers 134 include at least one of ZrO₂, Nb₂O₅, Ta₂O₅, SiₓN_{y}, Si, Ge GaP, InP, and PbS so as to have a high refractive index. For example, the refractive index of ZrO₂ is about 2.2. In some embodiments, ZrO₂, Nb₂O₅, Ta₂O₅, and SiₓN_{y} may be used to scatter visible light, while Si, Ge GaP, InP, and PbS may be used to scatter infrared (IR). In addition, the diameter d of each of the first fillers 134 is in a range from 0.1 μm to 1 μm. If the diameter d of the first filler 134 is less than 0.1 μm, the scattering performance of light diffuser 130 would be unstable.

Since the first fillers 134 dispersed in the main body 132 of the light diffuser 130 have high refractive index, and the first fillers 134 include at least one of ZrO₂, Nb₂O₅, Ta₂O₅, SiₓN_{y}, Si, Ge GaP, InP, and PbS, the light diffuser 130 can have high scattering capability and prevent photolysis. Moreover, the first fillers 134 have low reactivity with organics, and thus the selection of materials for the main body 132 of the light diffuser 130 is more flexible. As a result, the main body 132 with the first fillers 134 may be formed over the semiconductor substrate 110 by spin coating without a compression molding process.

In some embodiments, there is no TiO₂ located in the main body 132 of the light diffuser 130 because TiO₂ has several disadvantages of strong photolysis, unstable scattering performance for low wavelength (e.g., smaller than 450 nm), high reactivity with organics, the acceleration effect of reaction (which is difficult to formulate photoresist), and high yellow index.

Furthermore, a refractive index of the first fillers 134 is higher than a refractive index of the main body 132 the first fillers 134. Larger difference between the refractive index of the first fillers 134 and the refractive index of the main body 132 may achieve better scattering performance of the light diffuser 130. For example, the refractive index of ZrO₂ (i.e., the first fillers 134) is about 2.2, and the refractive index of epoxy or acrylic resin (i.e., the main body 132) is about 1.5. In some embodiments, the weight ratio of the first fillers 134 to the light diffuser 130 (i.e., the combination of the main body 132 and the first fillers 134) is in a range from 10% to 30%. As a result of such a configuration, the light diffuser 130 may have good uniformity and intensity of illuminance during operation.

In some embodiments, the image sensor package 100 optionally includes a metal-insulator-metal (MIM) structure 120 between the light diffuser 130 and the semiconductor substrate 110. The MIM structure 120 includes a first metal layer 122, an insulating layer 124, and a second metal layer 126. The insulating layer 124 is between the first metal layer 122 and the second metal layer 126. The present disclosure is not limited to the number of metal layers and the number of insulating layers. The MIM structure 120 can narrow the full width at half maximum (FWHM) of light transmitted to the photoelectric conversion region 112, such that the image sensor package 100 can produce a high signal-to-noise (S/N) ratio. However, the MIM structure 120 has the issues of blue shift and angle dependence. The light diffuser 130 can help the image sensor package 100 to reduce a blue shift, and decrease the decay of the angular response at large angles of incidence.

In some embodiments, the light diffuser 130 is directly on or in contact with the MIM structure 120 or the semiconductor substrate 110 due to spin coating process. In the following description, a manufacturing method of the image sensor package 100 of FIG. 1 will be explained.

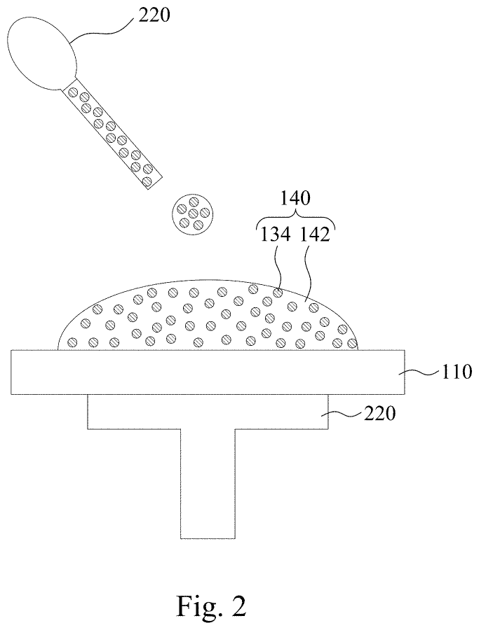

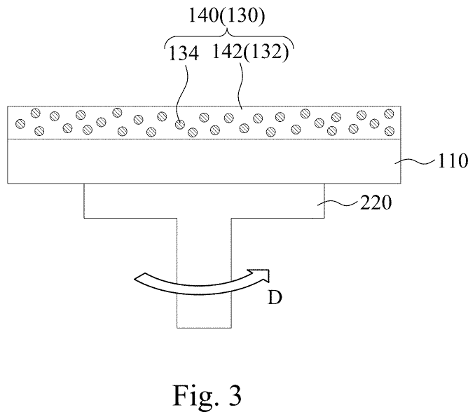

FIGS. 2 and 3 are schematic views at various stages of a manufacturing method of the image sensor package 100 of FIG. 1. In order to simplify the drawings, the MIM structure 120 shown in FIG. 1 is omitted. Referring to FIG. 2, the manufacturing method of the image sensor package 100 includes mixing the first fillers 134 with a resin 142, such as epoxy or acrylic resin, to form a solution 140. The resin 142 may be referred to as a photoresist. The first fillers 134 include at least one of ZrO₂, Nb₂O₅, Ta₂O₅, SiₓN_{y}, Si, Ge GaP, InP, and PbS, and the diameter d (see FIG. 1) of each of the first fillers 134 is in a range from 0.1 μm to 1 μm. Thereafter, the solution 140 having the mixed resin 142 and the first fillers 134 is dispensed to the semiconductor substrate 110 on a wafer stage 110 by a dispenser 220.

As shown in FIGS. 2 and 3, after the dispenser 220 drops the solution 140 over the semiconductor substrate 110, the wafer stage 110 may be rotated to spread the solution 140 such that the solution 140 covers the semiconductor substrate 100. The aforesaid process is spin coating. Afterwards, the solution 140 may be cured to form the light diffuser 130. In other words, the resin 142 is cured to be the main body 132 of the light diffuser 130.

It is to be noted that the connection relationships, materials, and advantages of the aforementioned elements will not be described again in the following description. In the following description, experimental results of the light diffuser during operation will be described.

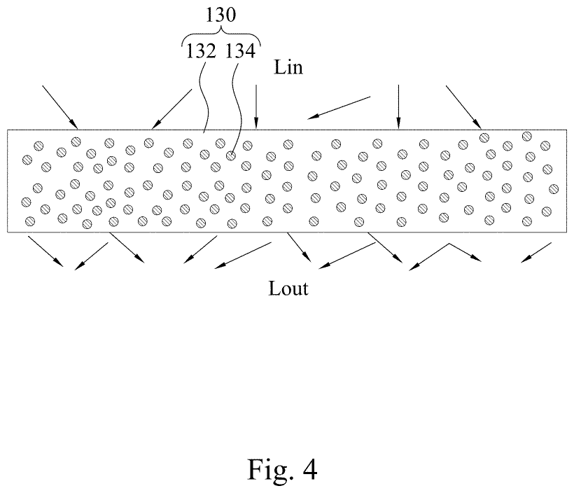

FIG. 4 is a schematic view of the light diffuser 130 when light passes through according to one embodiment of the present disclosure. As shown in FIG. 4, light Lin enters the top surface of the light diffuser 130, and then the first fillers 134 in the main body 132 can refract the light Lin, thereby forming scattering light Lout that irradiates from the bottom surface of the light diffuser 130. Due to the first fillers 134 in the main body 132, the scattering light Lout can be uniform and can maintain a desired luminous intensity.

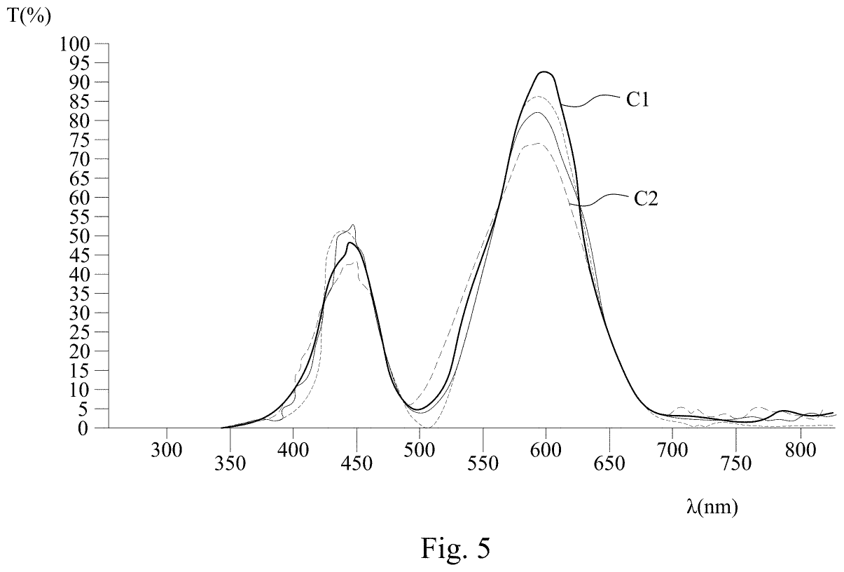

FIG. 5 is a Transmission rate-Wavelength relationship chart with respect to incident light with different incident angles passing through the light diffuser 130 of the image sensor package 100 of FIG. 1. As shown in FIG. 1 and FIG. 5, the incident light L1 vertically enters the light diffuser 130, and a curve C1 corresponding to different wavelengths of the incident light L1 with no incident angle is obtained. Moreover, the incident light L2 enters the light diffuser 130 with an incident angle 30 degrees, and a curve C2 corresponding to different wavelengths of the incident light L2 with the incident angle 30 degrees is obtained. Based on the data of the curves C1 and C2, differences between the curves C1 and C2 are mainly at wavelengths about 450 nm and about 600 nm. Although different incident angles affect the transmission rates of the light diffuser 130 at the tips of the curves C1 and C2, the distributions of the curves C1 and C2 are similar. That is, the light diffuser 130 has good scattering performance to improve the uniformity of light.

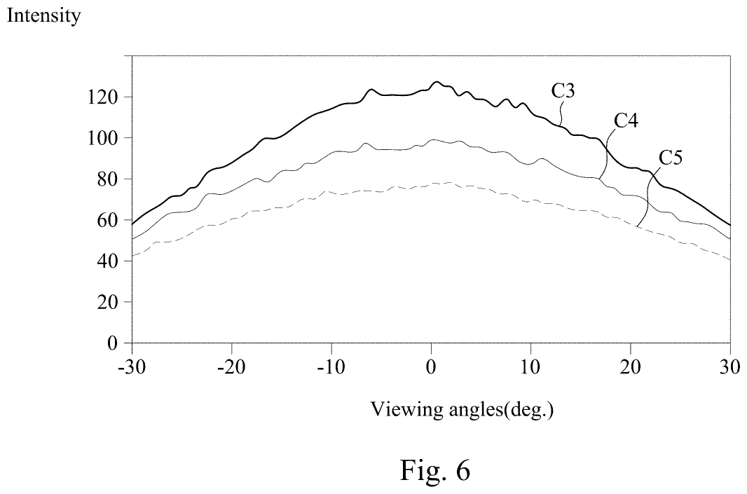

FIG. 6 is a Luminous intensity-Viewing angle relationship chart with respect to two light diffusers and one dry film, in which the two light diffusers include different proportions of fillers. As shown in FIG. 6, a curve C3 corresponds to a first light diffuser that includes a 20% weight ratio of fillers to the first light diffuser. In other words, the proportion by weight of the particles of the filler in the first light diffuser is 20%. A curve C4 corresponds to a second light diffuser that includes a 40% weight ratio of the fillers to the second light diffuser. In other words, the proportion by weight of the fillers in the second light diffuser is 40%. Furthermore, a curve C5 corresponds to a dry film, such as a diffuser sheet for bonding on a substrate.

According to the data of the curve C3, (Iₘₐₓ−Iₘᵢₙ)/Iₘₑₐₙ is about 75.3%, where Iₘₐₓ is the intensity value at 0 degree, Iₘᵢₙ is the intensity value at ±30 degrees, and Iₘₑₐₙ is (Iₘₐₓ+Iₘᵢₙ)/2. Based on the aforementioned formula, (Iₘₐₓ−Iₘᵢₙ)/Iₘₑₐₙ with respect to the curve C4 is about 62.5%, and (Iₘₐₓ−Iₘᵢₙ)/Iₘₑₐₙ with respect to the curve C5 is about 62.2%. Accordingly, the weight ratio of the fillers can be increased to improve the uniformity of illuminance of the light diffuser.

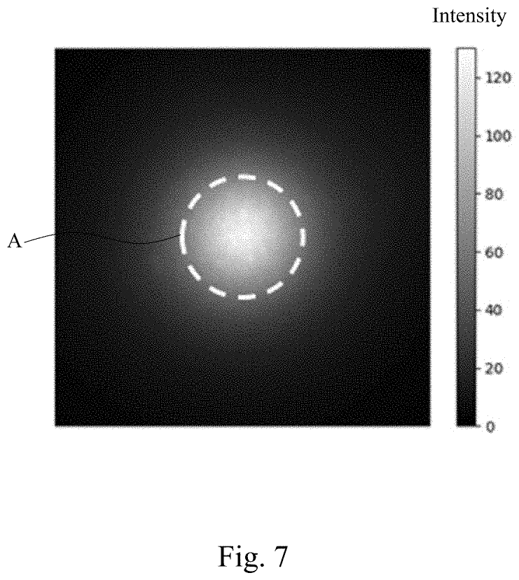

FIG. 7 is a distribution diagram of luminous intensity with respect to the light diffuser including a lower proportion of the fillers of FIG. 6 after light passing through the light diffuser. As shown in FIG. 6 and FIG. 7, the distribution diagram of the luminous intensity in FIG. 7 corresponds to the curve C3 of FIG. 6. That is, FIG. 7 is an experimental result with respect to the light passing through the first light diffuser that includes a 20% weight ratio of the fillers. An area A shown in FIG. 7 is defined by viewing angles in a range from +30 degrees to −30 degrees for the first light diffuser. The area A shows good luminous intensity of the first diffuser corresponding to the curve C3. The luminous intensity of the first diffuser is better than the luminous intensity of each of the second diffuser (corresponding to the curve C4) and the dry film (corresponding to the curve C5). Accordingly, although the weight ratio of the fillers can be increased to improve the uniformity of illuminance of the light diffuser, lower weight ratio of the fillers may maintain the luminous intensity of the light diffuser.

In some embodiments, the weight ratio of the first fillers (e.g., ZrO₂) to the light diffuser may be in a range from 10% to 30%. In some embodiments, the weight ratio of second fillers (e.g., SiO₂) to the light diffuser may be in a range from 20% to 50%. Based on the aforementioned ranges with respect to the weight ratio of the fillers, the light diffuser may have a balance between uniformity and intensity of illuminance.

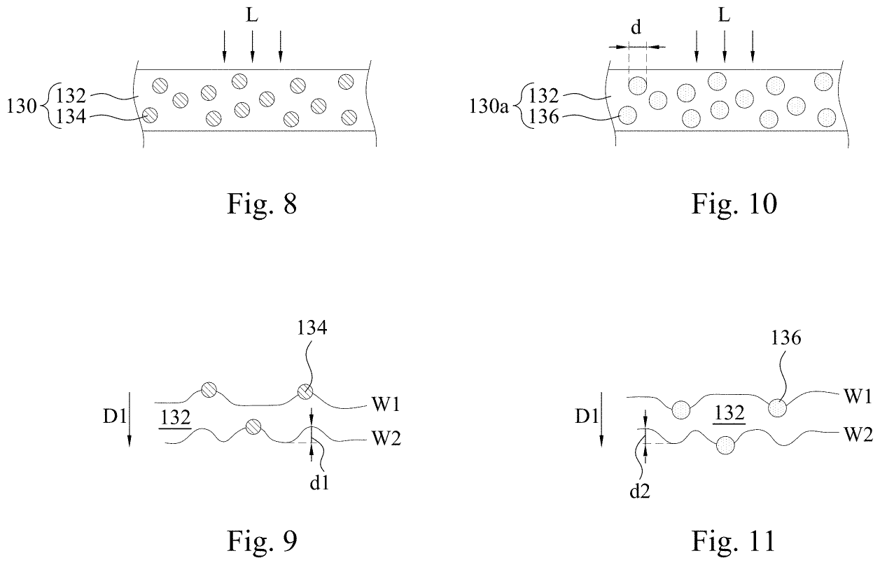

FIG. 8 is a partial enlarged view of the light diffuser 130 of FIG. 1. FIG. 9 is a schematic view for a phase contrast d1 which occurs in the light diffuser 130 of FIG. 8. As shown in FIG. 8 and FIG. 9, when light L enters the light diffuser 130, the light L is transmitted to the first fillers 134 in a direction D1. Phase contrast is dominated by nH/n0, where nH is the refractive index of the first fillers 134, and n0 is the refractive index of the main body 132 of the light diffuser 130. In some embodiments, the refractive index of the first fillers 134 (e.g., ZrO₂) is about 2.2, and the refractive index of the main body 132 (e.g., epoxy resin) is about 1.5.

When the light L is transmitted to the first fillers 134 that the light L encounters first, a wave front W1 is formed because the first fillers 134 that the light L encounters first reduce the velocity of the light L. Thereafter, when the wave front W1 is transmitted to the first fillers 134 that the light L encounters later, a wave front W2 is formed because the first fillers 134 that the light L encounters later reduce the velocity of the wave front W1. As a result of such a configuration, the phase contrast d1 can be formed. The arrangement of the first fillers 134 in the main body 132 shown in FIG. 9 is merely an example, and the present disclosure is not limited in this regard.

FIG. 10 is a partial enlarged view of a light diffuser 130a according to one embodiment of the present disclosure. FIG. 11 is a schematic view for a phase contrast d2 which occurs in the light diffuser 130a of FIG. 10. As shown in FIG. 10 and FIG. 11, the light diffuser 130a includes a plurality of second fillers 136 uniformly dispersed in the main body 132. The second fillers 136 are not regularly arranged in the main body 132. The refractive index of the second fillers 136 is lower than the refractive index of the main body 132. In some embodiments, the second fillers 136 include SiO₂, and the diameter d of each of the second fillers 136 is in a range from 1 μm to 10 μm.

When the light L enters the light diffuser 130a, the light L is transmitted to the second fillers 136 in the direction D1. Phase contrast is dominated by n0/nL, where nL is the refractive index of the second fillers 136, and n0 is the refractive index of the main body 132 of the light diffuser 130a. In some embodiments, the refractive index of the second fillers 136 (e.g., SiO₂) is about 1.47, and the refractive index of the main body 132 (e.g., epoxy resin) is about 1.5.

When the light L is transmitted to the second fillers 136 that the light L encounters first, a wave front W1 is formed because the second fillers 136 that the light L encounters first increase the velocity of the light L. Thereafter, when the wave front W1 is transmitted to the second fillers 136 that the light L encounters later, a wave front W2 is formed because the second fillers 136 that the light L encounters later increase the velocity of the wave front W1. As a result of such a configuration, the phase contrast d2 can be formed. The arrangement of the second fillers 136 in the main body 132 shown in FIG. 11 is merely an example, and the present disclosure is not limited in this regard.

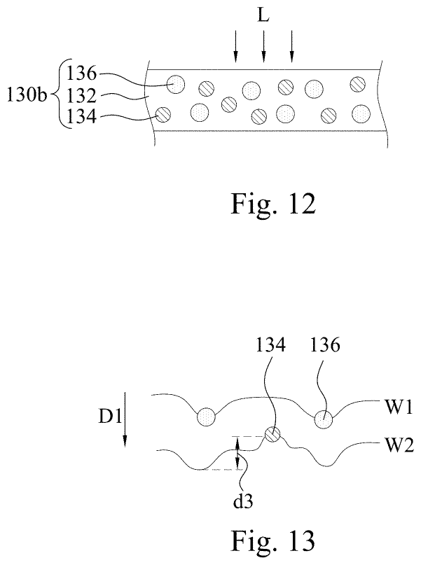

FIG. 12 is a partial enlarged view of a light diffuser 130b according to one embodiment of the present disclosure. FIG. 13 is a schematic view for a phase contrast d3 which occurs in the light diffuser 130b of FIG. 12. As shown in FIG. 12 and FIG. 13, the light diffuser 130b includes the main body 132, the first fillers 134 of FIG. 8, and the second fillers 136 of FIG. 10. The first fillers 134 and the second fillers 136 are mixed in the main body 132. The first fillers 134 and the second fillers 136 are uniformly dispersed in the main body 132 of the light diffuser 130b, but not regularly arranged in the main body 132. The refractive index of the second fillers 136 is lower than the refractive index of the first fillers 134, and is lower than the refractive index of the main body 132. In some embodiments, the weight ratio of the second fillers 136 to the light diffuser 130b (i.e., the combination of the main body 132, the first fillers 134, and the second fillers 136) is in a range from 20% to 50%.

When the light L enters the light diffuser 130b, the light L is transmitted to the second fillers 136 in the direction D1. Phase contrast is dominated by nH/nL, where nH is the refractive index of the first fillers 134, and nL is the refractive index of the second fillers 136. In some embodiments, the refractive index of the first fillers 134 (e.g., ZrO₂) is about 2.2, and the refractive index of the second fillers 136 (e.g., SiO₂) is about 1.47.

When the light L is transmitted to the second fillers 136 that the light L encounters first, a wave front W1 is formed because the second fillers 136 that the light L encounters first increase the velocity of the light L. Thereafter, when the wave front W1 is transmitted to the first fillers 134 that the light L encounters later, a wave front W2 is formed because the first fillers 134 that the light L encounters later reduce the velocity of the wave front W1. As a result of such a configuration, the phase contrast d3 can be formed. The arrangement of the first fillers 134 and the second fillers 136 in the main body 132 shown in FIG. 13 is merely an example, and the present disclosure is not limited in this regard.

Referring back to FIG. 2, the manufacturing method of the light diffuser 130b further includes prior to dispensing the solution 140 to the semiconductor substrate 110, mixing second fillers 136 with the resin 142, wherein the refractive index of the second fillers 136 is lower than the refractive index of the first fillers 134. As a result, the solution 140 may include the first fillers 134 and the second fillers 136. Thereafter, the solution 140 may be cured to form the light diffuser 130b of FIG. 12.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A light diffuser, comprising:
a main body; and
a plurality of first fillers dispersed in the main body, wherein the first fillers comprise at least one of ZrO₂, Nb₂O₅, Ta₂O₅, SiₓN_{y}, Si, Ge GaP, InP, and PbS, and a diameter of each of the first fillers is in a range from 0.1 μm to 1 μm.

2. The light diffuser of claim 1, wherein a refractive index of the first fillers is higher than a refractive index of the main body.

3. The light diffuser of claim 1, wherein a weight ratio of the first fillers to a combination of the main body and the first fillers is in a range from 10% to 30%.

4. The light diffuser of claim 1, further comprising:
a plurality of second fillers dispersed in the main body, wherein a refractive index of the second fillers is lower than a refractive index of the first fillers.

5. The light diffuser of claim 4, wherein the refractive index of the second fillers is lower than a refractive index of the main body.

6. The light diffuser of claim 4, wherein the second fillers comprise SiO₂.

7. The light diffuser of claim 4, wherein a diameter of each of the second fillers is in a range from 1 μm to 10 μm.

8. The light diffuser of claim 4, wherein a weight ratio of the second fillers to a combination of the main body, the first fillers, and the second fillers is in a range from 20% to 50%.

9. The light diffuser of claim 1, wherein the main body is a photoresist layer comprising epoxy or acrylic resin.

10. The light diffuser of claim 1, wherein there is no TiO₂ located in the main body.

11. An image sensor package, comprising:
a semiconductor substrate comprising a photoelectric conversion region; and
a light diffuser over the semiconductor substrate and configured to scatter incident light to the photoelectric conversion region, the light diffuser comprising:
a main body; and
a plurality of first fillers dispersed in the main body, wherein the first fillers comprise at least one of ZrO₂, Nb₂O₅, Ta₂O₅, SiₓN_{y}, Si, Ge GaP, InP, and PbS, and a diameter of each of the first fillers is in a range from 0.1 μm to 1 μm.

12. The image sensor package of claim 11, further comprising:
a metal-insulator-metal (MIM) structure between the light diffuser and the semiconductor substrate.

13. The image sensor package of claim 12, wherein the light diffuser is directly on the MIM structure.

14. The image sensor package of claim 11, wherein a refractive index of the first fillers is higher than a refractive index of the main body.

15. The image sensor package of claim 11, further comprising:
a plurality of second fillers dispersed in the main body, wherein a refractive index of the second fillers is lower than a refractive index of the first fillers and a refractive index of the main body.

16. The image sensor package of claim 15, wherein the second fillers comprise SiO₂.

17. The image sensor package of claim 15, wherein a diameter of each of the second fillers is in a range from 1 μm to 10 μm.

18. The image sensor package of claim 15, wherein a weight ratio of the second fillers to a combination of the main body, the first fillers, and the second fillers is in a range from 20% to 50%.

19. A manufacturing method of an image sensor package, comprising:
mixing a plurality of first fillers with a resin to form a solution, wherein the first fillers comprise at least one of ZrO₂, Nb₂O₅, Ta₂O₅, SiₓN_{y}, Si, Ge GaP, InP, and PbS, and a diameter of each of the first fillers is in a range from 0.1 μm to 1 μm;
dispensing the solution to a semiconductor substrate;
spreading the solution to cover the semiconductor substrate by spin coating; and
curing the solution to form a light diffuser, wherein the resin is cured to be a main body of the light diffuser.

20. The manufacturing method of the image sensor package of claim 19, further comprising:
prior to dispensing the solution to the semiconductor substrate, mixing a plurality of second fillers with the resin, wherein a refractive index of the second fillers is lower than a refractive index of the first fillers.
